(19) United States
(12) Patent Application Publication
(10) Pub. No.: US 2004/0123802 A1
(43) Pub. Date: Jul. 1, 2004

(54) Method and system for making p-type transparent conductive films

(76) Inventors: Chorng-Jye Huang, Hsinchu (TW); Shih-Cheng Lin, Hsinchu (TW); Cheng-Ting Chen, Hsinchu (TW); Lee-Ching Kuo, Hsinchu (TW)

Correspondence Address: BIRCH STEWART KOLASCH & BIRCH, PO BOX 747, FALLS CHURCH, VA, 22040-0747, US

(21) Appl. No.: 10/409,099

(22) Filed: Apr. 9, 2003

(30) Foreign Application Priority Data
Dec. 31, 2002 (TW) 091138078

(51) Int. Cl. C23C 16/00

(52) U.S. Cl. 118/722; 427/248.1; 427/595; 118/50.1; 118/620

(57) ABSTRACT

A method for making p-type transparent conductive films and the corresponding system are disclosed. A laser beam is used as the evaporation source of a target, so that the target containing a group-III element vaporizes and forms a coating on a substrate. At the same time, a gas to be mingled into the coating is made into plasma to increase its activity. The gas contains a group-V element. The particles in the target have reactions with the plasma so that the coating thus formed contain both group-III and group-V elements, with the concentration of the group-V element higher than that of group-III element. This achieves the goal of making a p-type transparent conductive film.

### BACKGROUND OF THE INVENTION

1. Field of Invention

The invention relates to a coating method and the corresponding system. In particular, the invention pertains to a method for making p-type transparent conductive films and the associated system.

2. Related Art

In the mechanics, opto-electronics, or semiconductor industries, to endow a material with particular properties thin-films are often formed on the surface of the material using various kinds of methods. The coating or deposition of such films is achieved by accumulating layers of particles from gases in the form of atoms, ions or molecules. Therefore, it can arrive at thin-film coatings with special structures and functions that normally cannot be achieved using thermal equilibrium methods.

For example, transparent conductive films with both transparent and conductive properties are widely used by the opto-electronics industry. Existing transparent conductive films are mainly of n-type. That is, they are films using electrons for conduction and have applications limited to passive conduction. If a p-type transparent conductive film can be formed, these two types of films can be combined to make transparent active devices, which may have applications in new-type opto-electronic devices. However, in the thin film processes, performing a single-element p-type doping will increase the energy of the crystal structure such that no stable crystal can be formed.

Most of the existing coating technologies control gas particles to form thin films through physical vapor deposition (PVD) or chemical vapor deposition (CVD). The PVD utilizes a physics mechanism to control thin-film deposition without involving any chemical reaction. Methods such as thermal resistance, radiation, inductance, electron beams, electric arcs, ionization or ion beams are used to vaporize the materials to combine with the reaction gas for coating. The CVD is one type of thermal chemistry processes. Chemical reactions on the volatile compound gas that contains the material to be coated make the products deposited on a heated substrate. Both methods require the use of some gas while coating.

However, the gas required by some special coating is less active and less ionized. Therefore, it is hard to enter the structure. For example, to make p-type transparent conductive films, nitrogen replaces oxygen to enter the structure of an oxide. However, both the activity and ionization of nitrogen gas are not good enough. Thus, it rarely participates in the reaction. This is why there is no ideal manufacturing method for making p-type transparent conductive films.

### SUMMARY OF THE INVENTION

In view of the foregoing, the invention provides a method and system for making a p-type transparent conductive film. A laser beam is used as the evaporation source of a target, evaporating the material for coating. At the same time, a gas to be blended into the thin film is made into plasma to increase its activity. The vaporized coating material and the plasma undergo reactions to form the desired p-type transparent conductive film.

The disclosed method performs the coating process in a vacuum chamber, including the steps of providing a substrate, providing a target doped with a group-III element, providing a laser beam projecting onto the target for providing the energy to vaporize part of the target, forming a film on the substrate; exciting a gas to be blended into the film into plasma, the gas containing a group-V element; reacting the plasma and the vaporized target particles so that the film contains both the group-V and group-III elements with the concentration of the former higher than that of the latter. Since the film structure formed according to the invention contains both group-V and group-III elements, the influence on the crystal structure energy is lower.

The plasma is an electrically neutral gas with electrons, ions and non-ionized gas in equilibrium. The group-V negative ions contained in the plasma have a higher activity then atoms, they are likely to combine with unbonded positive ions on the substrate surface, forming a thin film containing group-V atoms.

The invention also disclosed a system that implements the above method. The system contains: a target, which is installed in a vacuum chamber and doped with a group-III element; a laser source, which casts a laser beam on the target for providing the energy to vaporize part of the target; a substrate, which has an angle with the target for the vaporized target particles to deposit on the substrate surface; an excitation source, which excites a gas to be blended into the film into plasma, the gas containing a group-V element. The excited plasma has reactions with the vaporized target particles so that the film simultaneously contains group-V and group-III elements, with the concentration of the group-V element higher than that of the group-III element.

### BRIEF DESCRIPTION OF THE DRAWINGS

The invention will become more fully understood from the detailed description given hereinbelow illustration only, and thus are not limitative of the present invention, and wherein:

FIG. 1 is a schematic view of the system in an embodiment of the invention;

FIG. 2 is a flowchart of an embodiment of the invention;

FIG. 3 is a picture of the ZnO film made in accordance with the invention;

FIG. 4 is an X-ray diffraction diagram of the disclosed ZnO film; and

FIG. 5 is a penetration rate diagram of the disclosed ZnO film.

### DETAILED DESCRIPTION OF THE INVENTION

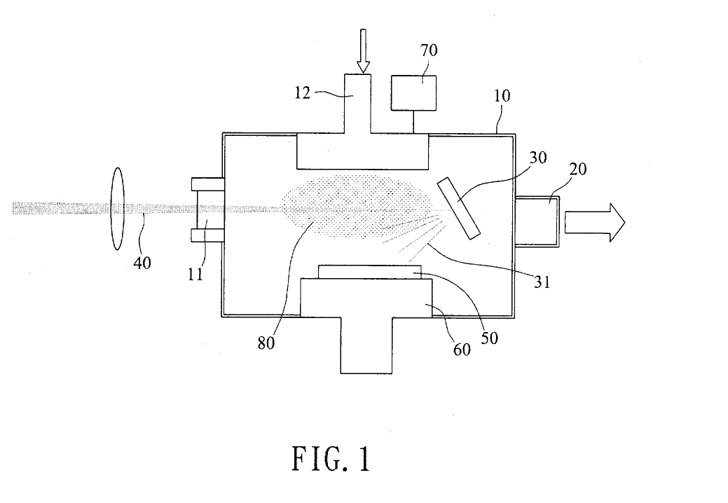

The system for producing p-type transparent conductive films provided by the invention can be explained with the help of an embodiment shown in FIG. 1. As shown in the drawing, the coating process is performed in the vacuum chamber 10. The vacuum chamber 10 is connected with a vacuum pump 20 to empty air inside the chamber. The target 30 is installed inside the vacuum chamber 10 in alignment with a quartz window 11. The material of the target 30 is Ga-doped ZnO. In addition, an excimer laser (not shown) is required to project a laser beam 40 through the quartz window 11 on the target 30, providing energy for vaporizing part of the target 30. The substrate 50 is installed at the bottom of the chamber 10. A heater 60 is provided under the substrate 50. The substrate 50 and the target 30 have an angle, so that the vaporized target particles 31 are deposited on the surface of the substrate 50 to form a coating film. The top of the chamber 10 is installed with an excitation source 70 for exciting the nitrogen-rich gas entered via the gas inlet 12 into plasma 80. The excited plasma 80 interacts with the target particles 31, making the film containing both N and Ga. The concentration of nitrogen is higher than that of the gallium. A p-type transparent conductive film is thus formed.

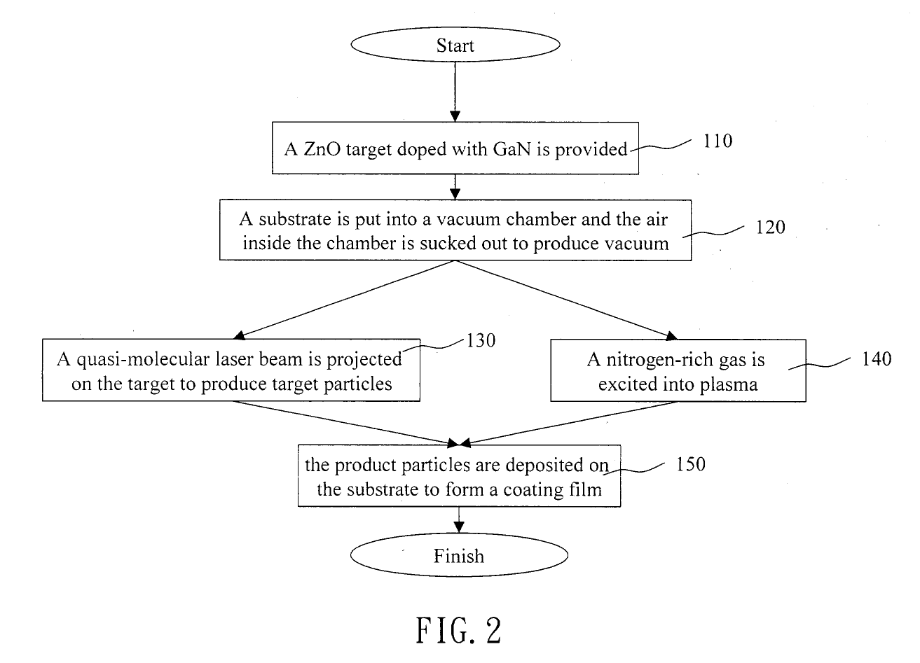

The disclosed method is depicted in FIG. 2. It includes the following steps. A ZnO target doped with Ga is provided (step 110). A substrate is put into a vacuum chamber and the air inside the chamber is sucked out to produce vacuum (step 120). The pressure on the coating film is between 0.1 mTorr and 5 Torr. An excimer laser beam is projected on the target to produce target particles (step 130). At the same time, a nitrogen-rich gas is excited into plasma (step 140). Allowing the plasma to interact with the target particles, the product particles are deposited on the substrate to form a coating film (step 150). The film contains both N and Ga and the concentration of the former is higher than that of the latter.

In the current embodiment, we use a KrF excimer laser with a power between 20 mJ/cm2 and 1000 mJ/cm2. The excitation frequency of the plasma ranges between 1000 Hz and 200 MHz. The target is made of ZnO doped with group-III elements such as Al, Ga, and In. The group-V elements contained in the plasma gas can be one of N, P, and As.

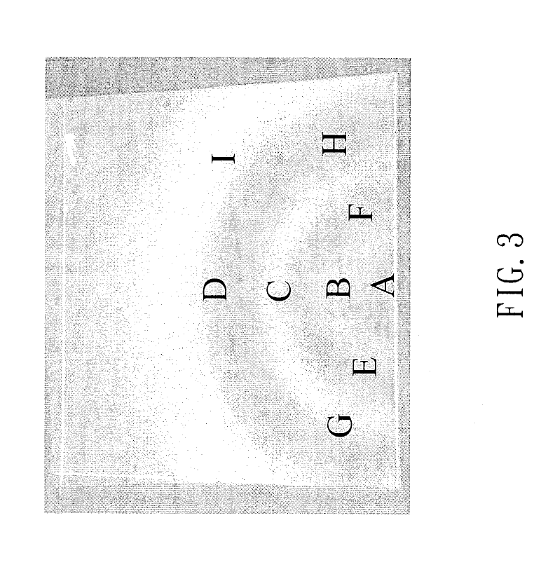

To demonstrate the effects of the invention, please refer to FIG. 3. It is a picture of the ZnO film made according to the invention. The resistance values are points A to I are measured and listed in Table I.

TABLE I

| Label | Type | Resistance |
|---|---|---|
| A | n | 6.4E+03 |
| B | n | 2.0E+04 |
| C | n | 6.6E+04 |
| D | Undetermined | 1.8E+05 |
| E | Undetermined | 6.6E+04 |
| F | Undetermined | 4.8E+04 |
| G | p | 5.0E+05 |
| H | p | 4.6E+05 |
| I | p | 1.0E+06 |

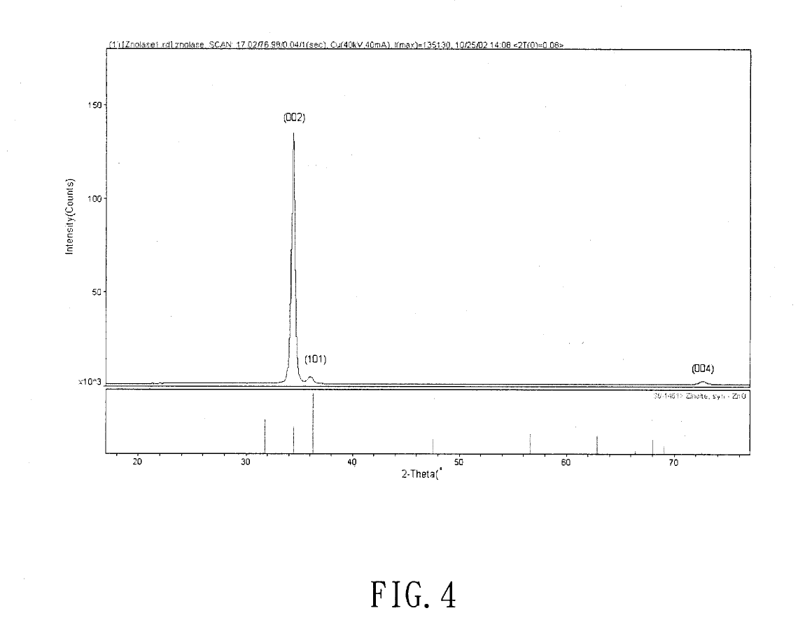

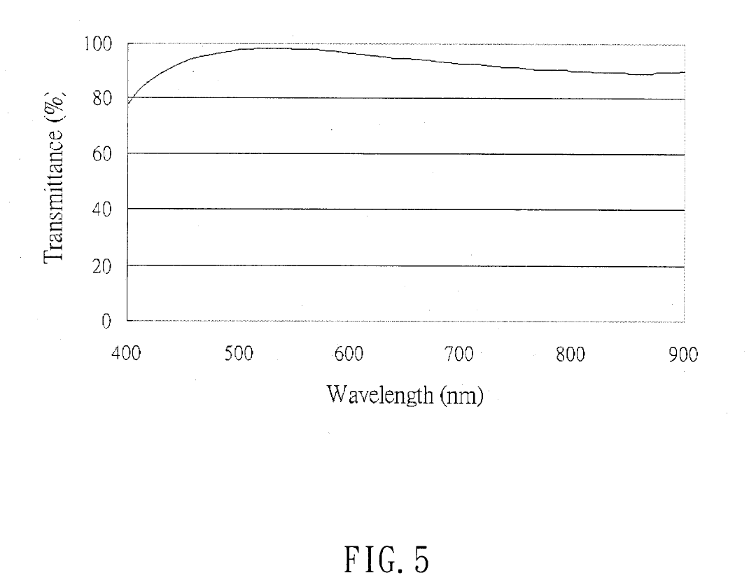

The area around point I is measured using the Hall effect to be a p-type ZnO thin film, with a resistance of 22 Ω-cm, a mobility of 0.25 cm2/V.s, and a carrier concentration of 1.87E18/cm3. Please refer to FIG. 4 for the film properties. It shows the X-ray diffraction pattern of the ZnO film. Observing its diffraction peaks, one sees that it has a very strong C-axis crystal direction, showing that it is a crystal state. As shown in FIG. 5, the penetration rate of the ZnO film in the visible region is above 80%. Therefore, the disclosed ZnO film is very transparent.

Certain variations would be apparent to those skilled in the art, which variations are considered within the spirit and scope of the claimed invention.

What is claimed is:

1. A method for making a p-type transparent conductive film performed in a vacuum chamber comprising the steps of:
providing a substrate, which is installed inside the vacuum chamber;
providing a target, which is doped with a group-III element;
projecting a laser beam on the target for providing the energy to vaporize part of the target into particles;
exciting a gas, which contains a group-V element, to form plasma to interact with the target particles; and
depositing the target particles on the surface of the substrate, forming the film that simultaneously contains a group-V element and a group-III element with the concentration of the former higher than that of the latter.

2. The method of claim 1, wherein the target is made of ZnO.

3. The method of claim 1, wherein the group-III element doped into the target is selected from the group consisting of Al, Ga, and In.

4. The method of claim 1, wherein the laser is an excimer laser.

5. The method of claim 4, wherein the excimer laser is a KrF excimer laser with a power between 20 mJ/cm2 and 1000 mJ/cm2.

6. The method of claim 1, wherein the excitation frequency in the step of exciting a gas to form plasma is between 1000 Hz and 200 MHz.

7. The method of claim 1, wherein the group-V element contained in the gas is selected from the group consisting of N, P, and As.

8. A system for making a p-type transparent conductive film in a vacuum chamber, comprising:
a target, which is installed inside the vacuum chamber and doped with a group-III element;
a laser source, which projects a laser beam on the target for providing energy to vaporize the target into particles;
a substrate, whose surface is deposited with the target particles to form a coating film; and
an excitation source, which excites a gas to be blended with the film into plasma, the gas containing a group-V element;
wherein the excited plasma interacts with the target particles so that the coating film formed on the substrate surface contains simultaneously a group-V element and a group-III element with the concentration of the former higher than that of the latter.

9. The system of claim 8, wherein the target is made of ZnO.

10. The system of claim 8, wherein the group-III element doped into the target is selected from the group consisting of Al, Ga, and In.

11. The system of claim 8, wherein the laser is an excimer laser.

12. The system of claim 11, wherein the excimer laser is a KrF excimer laser with a power between 20 mJ/cm2 and 1000 mJ/cm2.

13. The method of claim 8, wherein the excitation frequency in the step of exciting a gas to form plasma is between 1000 Hz and 200 MHz.

14. The method of claim 8, wherein the group-V element contained in the gas is selected from the group consisting of N, P, and As.
